(19) United States
(12) Patent Application Publication
(10) Pub. No.: US 2015/0380584 A1
(43) Pub. Date: Dec. 31, 2015

(54) SOLAR CELLS CONTAINING METAL OXIDES

(71) Applicants: Christiaan RICHTER, Boston, MA (US); NORTHEASTERN UNIVERSITY, Boston, MA (US)

(72) Inventors: Christiaan Richter, Boston, MA (US); Latika Menon, Malden, MA (US); Eugen Panaitescu, Brookline, MA (US)

(21) Appl. No.: 14/767,761

(22) PCT Filed: Feb. 12, 2014
(86) PCT No.: PCT/US14/16027

§ 371 Date: Aug. 13, 2015

Related U.S. Application Data
(60) Provisional application No. 61/764,980, filed on Feb. 14, 2013.

(51) Int. Cl. H01L 31/0352; H01L 31/032; H01L 31/18; H01L 31/04; H01G 9/20; H01L 31/0296; H01L 31/0224

(52) U.S. Cl. CPC H01L 31/035227; H01L 31/0296; H01L 31/0324; H01L 31/032; H01L 31/022466; H01L 31/04; H01G 9/2031; H01L 31/1884

(57) ABSTRACT

A solar cell includes a plurality of nanostructures. The nanostructures include a first metal oxide, each of the plurality of the nanostructures having a surface defining a cavity opening into an upper side. The solar cell further includes a layer of a second metal oxide disposed over the surface in at least some of the plurality of the nanostructures and a filler material disposed over the layer and filling at least partially the cavity of at least some of the plurality of the nano structures.

### RELATED APPLICATION

This application claims priority from U.S. Provisional Application Ser. No. 61/764,980, filed Feb. 14, 2014, which is hereby incorporated by reference in its entirety.

### BACKGROUND

In recent years there has been progress in nanomaterials research for energy-related applications. Several nanomaterials demonstrate promise as candidates for transformative technologies including applications in next generation photovoltaics (PV). Theoretical efficiency limits for nano-PV is estimated to be 17% for single junction and 24% for tandem cells. These values at best reach parity with conventional silicon approaches. The true potential, if any, of nano-PV lies in realizing significant cost reductions and the use of stable earth abundant materials in small quantities. Currently the leading approach towards low cost nano-PV, receiving significant federal research funding annually, is organic (OPV) or hybrid organic solar technologies. Despite sustained effort a commercially viable solution that overcomes the major problems of OPV (instability and short exciton diffusion lengths) has remained elusive.

Another hybrid organic-inorganic alternative to OPV is the Dye Sensitized Solar Cell (DSSC). DSSC technology does may achieve complete charge separation on the order of 100 femtoseconds in optimized systems, something that no other current solar energy technology may rival. In a DSSC, light is absorbed only right at an interface by an organic sensitizer molecule anchored to the surface of a wide band semiconductor such as titanium dioxide nanoparticles. TiO₂, with its large conduction band density of states and reasonable electron mobility, has proven an excellent material to host ultrafast charge injection. Though the DSSC or Grätzel cell has been stuck at efficiencies around 10% for several decades, the major problem with DSSC technology is not so much its efficiency but the fact that DSSC technology has poor long term and environmental stability and has proven a particularly difficult challenge for large scale manufacturing.

### SUMMARY

In view of the foregoing, the Inventors have recognized and appreciated the advantages of solar cells comprising metal oxides and the methods of making and using same. In one embodiment, the fabrication of a solar cell using a nanostructure substrate and inorganic materials is provided. The solar cell may be an all-inorganic integrated metal-metal oxide solar cell.

Accordingly, provided in one embodiment is a solar cell including a plurality of nanostructures. The nanostructures include a first metal oxide, each of the plurality of the nanostructures having a surface defining a cavity opening into an upper side. The solar cell further includes a layer of a second metal oxide disposed over the surface in at least some of the plurality of the nanostructures and a filler material disposed over the layer and filling at least partially the cavity of at least some of the plurality of the nanostructures.

Provided in another embodiment is a method for fabricating a solar cell. The method includes disposing a layer comprising a metal on a surface of at least some of a plurality of nanostructures, the surface defining a cavity in the plurality of nanostructures. The method further includes forming a metal oxide layer by heat treating the layer comprising the metal, and disposing a filler material filling at least partially the cavity of at least some of the plurality of nanostructures.

Provided in another embodiment is a solar cell including a plurality of nanotubes comprising titania. Each of the plurality of the nanotubes has a surface defining a cavity opening into an upper side. The solar cell further includes a metal oxide layer disposed over the surface in at least some of the plurality of the nanotubes, a filler material disposed over the layer and filling at least partially the cavity of at least some of the plurality of the nanotubes, a first contact disposed on the upper side and in contact with the filler material, and a second contact disposed on a lower side of the nanotubes opposite the first contact.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1A-1C are schematic cross-section views of a solar cell, according to several exemplary embodiments.

FIG. 2 is graph illustrating the effective surface area of an array of nanotubes as a function of the length and diameter of the nanotubes, according to one exemplary embodiment.

FIG. 3A is a scanning electron microscope (SEM) image of a top view of a titania nanotube array, according to one exemplary embodiment.

FIG. 3B is a scanning electron microscope image of a bottom-side isometric view of a titania nanotube array, according to one exemplary embodiment.

FIG. 3C is a scanning electron microscope image of a side view of a titania nanotube array, according to one exemplary embodiment.

FIG. 3D is a scanning electron microscope image of a side view of a titania nanotube array, according to one exemplary embodiment.

FIG. 4A is a scanning electron microscope image of a top-side isometric view of a titania nanopore array, according to one exemplary embodiment

FIG. 4B is a scanning electron microscope image of a side view of a titania nanopore array, according to one exemplary embodiment.

FIG. 5 is a scanning electron microscope image of a top view of electrodeposited iron in a titania nanotube array, according to one exemplary embodiment.

FIG. 6 is a scanning electron microscope image of a top view of electrodeposited copper oxide in a titania nanotube array, according to one exemplary embodiment.

FIG. 7A-7B are scanning electron microscope images of top views of a titania nanotube array, according to one exemplary embodiment.

FIG. 7C-7D are scanning electron microscope images of top views of iron deposited in the titania nanotube array of FIGS. 7A-7B by thermal evaporation.

FIG. 8A is a scanning electron microscope image of a top view of a titania nanotube array, according to one exemplary embodiment.

FIG. 8B is a scanning electron microscope image of a top view of iron deposited in the titania nanotube array of FIG. 8A by thermal evaporation.

FIGS. 9A-9B are scanning electron microscope images of top views of a titania nanotube array, according to one exemplary embodiment.

FIG. 9C-9D are scanning electron microscope images of a top views of iron deposited in the titania nanotube array of FIGS. 9A-9B by thermal evaporation.

FIG. 10A is a scanning electron microscope image of a top-side isometric view of a titania nanopore array coated with iron, according to one exemplary embodiment.

FIG. 10B is an electron diffraction spectroscopy profile of the titania nanopore array of FIG. 10A.

FIG. 10C is a scanning electron microscope image of a top-side isometric view of the titania nanopore array of FIG. 10A.

FIG. 10D is an elemental map showing the titanium in the titania nanopore array of FIG. 10C.

FIG. 10E is an elemental map showing the iron in the titania nanopore array of FIG. 10C.

FIG. 11A is a scanning electron microscope image of a top-side isometric view of a titania nanotube array coated with iron, according to one exemplary embodiment.

FIG. 11B is an electron diffraction spectroscopy graph of the titania nanotube array of FIG. 11A.

FIG. 11C is a scanning electron microscope image of a top-side isometric view of the titania nanotube array of FIG. 11A.

FIG. 11D is an elemental map showing the titanium in the titania nanotube array of FIG. 11C.

FIG. 11E is an elemental map showing the iron in the titania nanotube array of FIG. 11C.

FIG. 12 illustrates the magnetic properties of an array of relatively long titania nanotubes before deposition of the metal, after deposition of the metal, and after annealing of the metal, according to one exemplary embodiment.

FIG. 13 illustrates the magnetic properties of an array of relatively short titania nanotubes before deposition of the metal, after deposition of the metal, and after annealing of the metal, according to one exemplary embodiment.

FIGS. 14-16 show x-ray diffraction (XRD) spectra of the nanotube array, according to several exemplary embodiments.

FIG. 17A is a scanning electron microscope image showing gold nanoparticles deposited onto the surface of a nanotube titania array, according to one exemplary embodiment.

FIG. 17B is a transmission electron microscope image showing gold nanoparticles deposited onto the surface of a nanotube titania array, according to one exemplary embodiment.

FIG. 17C is a graph illustrating the diameter of the nanoparticles and particle density as functions of deposition time, according to one exemplary embodiment.

FIG. 17D is a graph illustrating the surface coverage of the nanoparticles as a function of deposition time, according to one exemplary embodiment

FIG. 18 illustrates the band gap properties of several exemplary solar cell architectures according to one exemplary embodiment.

FIG. 19 shows current-resistance curve for a prototype nanotube solar cell according to one exemplary embodiment.

FIG. 20A is a scanning electron microscope image showing gold electrodes on a single titania nanotube, according to one exemplary embodiment.

FIG. 20B is a scanning electron microscope image showing a single gold electrode on a single titania nanotube, according to one exemplary embodiment.

FIG. 20C is a graph illustrating the relative resisitivities of the titania nanotube and anatase titania, according to one exemplary embodiment.

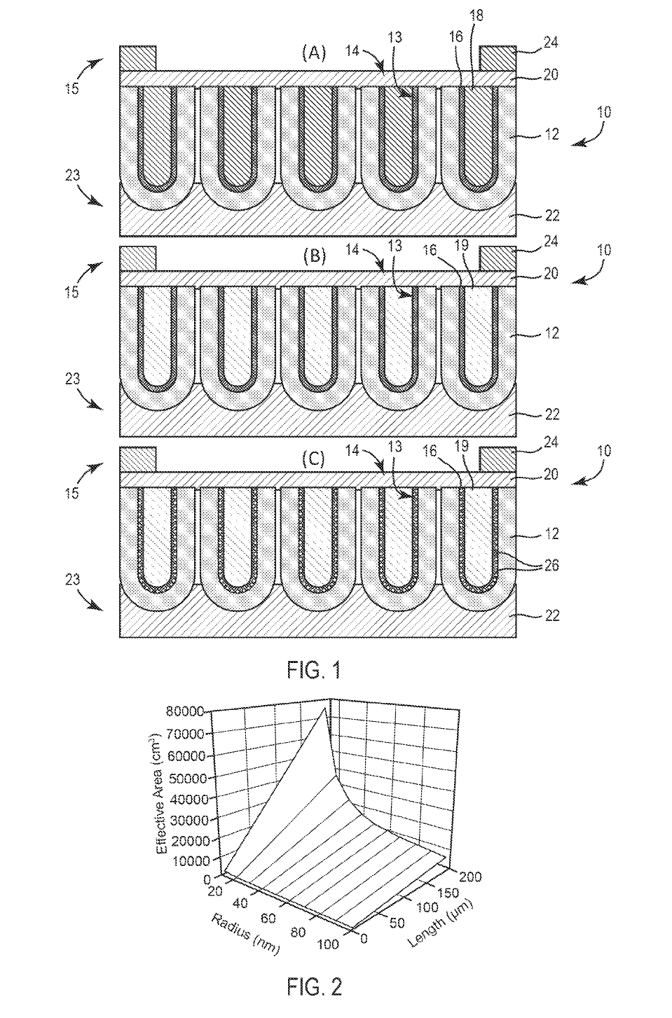

### DETAILED DESCRIPTION

Following below are more detailed descriptions of various concepts related to, and embodiments of, inventive solar cells and method for fabricating the same. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

Provided in one embodiment herein is a nano-photovoltaic cell comprising inorganic materials utilizing scalable low cost nano-fabrication techniques and stable, non-toxic earth abundant materials. The cell may be configured to have absorption occur close to an interface followed by fast charge separation. The cell may be further configured to have an improved stability and manufacturability compared to pre-existing technologies, such as DSSC technology. The method for forming the cell may employ self-ordering anodization and electrodeposition to provide a nano-scale, ordered, high surface area hetero-junctions needed for efficient conversion of solar energy. The manufacture of the cell may be achieved in a two-step electrochemical process that is scalable and inexpensive.

As shown in FIG. 1A-1C, the a solar cell 10 described in one embodiment herein includes a plurality of titanium dioxide (or titania (TiO₂)) nanostructures 12 forming an electron conductor layer and substrate for the remainder of the cell 10. The plurality of nanostructures 12 may be in the form of an array. The nanostructures 12 have a surface 13 defining a cavity 14 opening into an upper side 15 of the solar cell 10. The surface 13 is lined with a thin layer of a metal oxide 16, which plays the role of the solar energy absorber. By using an array of nanostructures 12 instead of a flat sheet, the potential surface area over which the metal oxide 16 may be disposed may be increased. The cavities 14 in the nanostructures 12 are filled at least partially (in some instances completely) with a conductor, such as a metal conductor 18 (see FIG. 1A), or a hole-conductor material 19 (see FIGS. 1B-1C). A first upper contact 20 and a second lower contact 22 are formed, respectively, on an upper side 15 and a lower side 23 of the nanostructures 12. The terms “first” and “second” herein are used merely to describe distinct entities and are not meant to denote any order. Conductive bus bar connectors 24 conductively couple the solar cell 10 to a bus bar. In some embodiments, nanoparticles 26 may be provided between the metal oxide 16 and the nanostructures 12.

### Electron Conductor Layer

An electron conductive layer may be one that comprises the plurality of nanostructures. The solar cell 10 includes of an array of nanostructures formed at least partially from titania, including, but not limited to nanotubes, nanopores, and nanowires. A method for preparing titania nanotubes prepared by anodization is described in detail in Published U.S. Application No. 2010/0024879, entitled “Titania Nanotubes Prepared by Anodization in Chloride-Containing Electrolytes,” filed Feb. 4, 2010, which is incorporated in its entirety herein.

Titania nanotube and nanopore arrays may be electrochemically synthesized with good control over the periodicity and tube dimensions. According to one exemplary embodiment, the nanotubes are formed on a precursor foil (e.g., a titanium foil) that is submerged in an electrolyte and anodized. The foil provides an anode which is electrically coupled to an inert cathode through a voltage source. Generally, a voltage source for use in the methods of the invention may supply a constant voltage in the range of about 0 to about 150V DC, and may supply a current in the range of at least 1.0 amp per cm² of anode surface area or higher.

When a suitable concentration of fluoride or chloride ions is included in the electrolyte the titanium foil is converted into titanium nanotubes as opposed to merely a compact oxide film. Not to be bound by any particular theory, but the halogen ions may periodically disrupt or etch the oxide film that forms as the anodizing process occurs. The secondary etching reaction causes the new oxide formation to continue by keeping the oxide layer thin at the nanotube floor and thus keep the nanotubes growing as long as the anodization field is applied.

According to an exemplary embodiment, the source of chloride ions in the electrolyte solution is from the dissociation of a chloride-containing salt or acid, or from another chloride donor. Any salt yielding chloride ions upon dissolution or acid releasing chloride upon dissociation in the electrolyte solution may be used, provided that the other ions do not interfere with the nanotube formation process. The solvent for the electrolyte solution may be water or another polar solvent such as dimethylsulfoxide, glycerol, formamide, or any mixture of polar solvents.

During anodization, the titanium metal foil is rapidly converted into titania. The process described above may be performed at higher speeds than a solvo- or hydro-thermal process, or much more expensive vacuum deposition methods. Nanotubes of the desired length for solar cell applications may be obtained in minutes or even tens of seconds. In one embodiment, the nanotubes may have a length of between 200 nm and 30 microns. In another embodiment, the nanotubes may have a length of between 1 microns and 20 microns. In another embodiment, the nanotubes may have a length of between 5 microns and 10 microns. In one embodiment, the nanotube walls have a thickness of between 2 nm and 10 nm. The anodization process may be scaled to fabricate nanotube arrays of a desired width (e.g., using a roll of foil that is several feet wide in an appropriately sized processing tank).

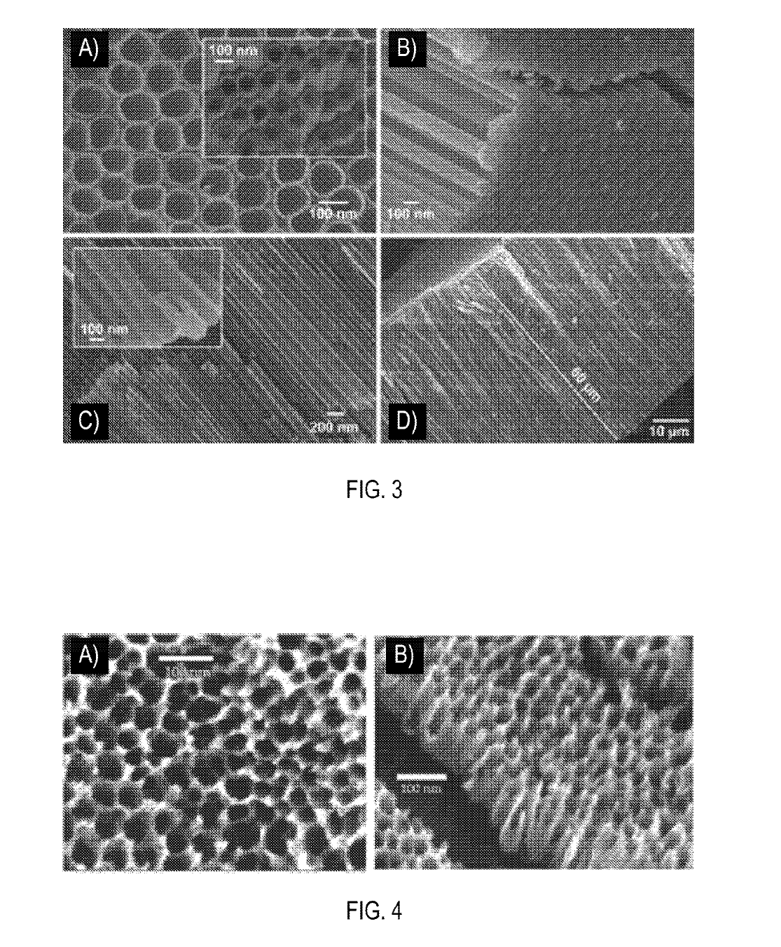

An exemplary array of nanotubes is shown in FIGS. 3A-3D. The nanotubes may be generally packed parallel to each other along one direction. The direction may be horizontal or vertical, or any suitable orientations. They may form an oriented, continuous nanostructure architecture that is optimized to provide an increased surface area exposed to an incident light source.

The foil may become degraded, or partially (or even entirely) consumed during the anodization process, as its mass is converted into titania nanotubes. The nanotubes may contain other materials, such as chloride or other elements that are present in the electrolyte solution. Carbon may be added to the titania nanotubes by introducing an organic acid, such as a carboxylic acid to the electrolyte solution. The combined oxidation and etching reaction is generally self-ordering and results in a generally uniform nanotube array on any exposed area of the precursor metal foil.

An exemplary array of nanopores is shown in FIGS. 4A-4B. The fabrication conditions, including the electrodeposition parameters, may be adjusted to fabricate nanopores as opposed to nanotubes. One distinction between a nanopore and a nanotube is that the later has a higher aspect ratio than the former. In one embodiment, nanopores are formed at a voltage below 8V, whereas nanotubes are formed at a voltage above 8V. The voltage values need not be limited to 8V, as by adjusting the other parameters, other voltage values may be obtained as the threshold to form a nanotube, as opposed to a nanopore.

The nanostructure may undergo a subsequent annealing step to improve the crystallinity of the material in the nanotubes. Not to be bound by any particular theory, but post-synthesis annealing may have effects on the crystallite size, orientation and nanotube morphology of the nanotubes. For example, in one embodiment, oxygen-rich annealing atmosphere may promote growth of large crystallites oriented along the tube axis (relevant for improved transport). In another embodiment, under nitrogen annealing, the crystallites may grow out of the nanotube (perpendicular to tube axis) resulting in destruction of tube morphology. This may be due to the effect of annealing atmosphere on the stoichiometry (for example oxygen-poor atmosphere may be resulting in TiO_{2-δ} rather than TiO₂), which in turn modifies the crystal lattice, lattice volume, etc. By controlling the synthesis parameters (oxygen pressure, annealing temperature, etc.), the nanotube structure may be optimized with regards to crystal structure before they are employed as photovoltaic anodes, as described below. Additional insight into charge mobility, free carrier densities and defects may be obtained by using ultrafast THz (or far-infrared). The annealing parameters (atmosphere, annealing time, rate, etc.) may therefore be chosen to optimize nanotube crystallinity, carrier mobility, charge transfer into, and charge transport within the nanotubes or pores. In one embodiment, the nanostructure is annealed at 400° C. for 1 hour. Other temperature and annealing time are also possible.

### Absorber Layer

An absorber layer may be one that comprises a metal oxide layer. The nanotubes or nanopores may be lined with a semi-insulating solar energy absorber layer. The absorber layer may be deposed on the interior surface defining the cavities, such as by being deposited with an appropriate process. The oriented structure of the nanostructure may increase the surface area confronting the incident light and therefore increases the surface area of the absorber layer and the efficiency of the solar cell. Use of the nanostructure architecture may increase the potential efficiency of the solar cell construction shown in FIG. 1 over a cell with similar chemistry and flat, thin film construction.

The absorber layer may be relative thin. For example, the layer may have a thickness of less than or equal to about 100 nm—e.g., less than or equal to about 50 nm, about 30 nm, about 20 nm, about 10 nm, or smaller.

Deposition of the absorber layer inside nanotubes may involve an electrochemical process, such as one in an electrochemical cell. According to one exemplary embodiment, the absorber layer is formed as a result of submerging the nanostructure array in an aqueous electrolyte and anodizing the array. In this embodiment, the nanostructure array provides an anode which is electrically coupled to an inert cathode through a voltage source. The electrolyte may contain a salt of the desired deposition material (e.g., the desired metal), and may include an acid or other substance to achieve a desired pH level to enhance the conductivity. The solvent for the electrolyte solution may be water or another polar solvent such as dimethylsulfoxide, glycerol, formamide, or any mixture of polar solvents. The deposition cycle may be completed rapidly, with the deposition of the metal forming the absorber layer on the order of minutes. Longer or shorter times may also be employed, depending on the materials involved.

Oxygen transfer may occur from the TiO₂ nanostructure array to the deposited metal. The transfer of oxygen may be controlled by annealing temperature and oxygen partial pressure to naturally obtain the desired thin metal oxide absorber layer on the surface of the nanostructure array by a self-limiting process. This approach may allow control over the thickness of the metal oxide layer throughout the interpenetrated nanostructure. In one embodiment, because the metal oxide layer formation may be a natural passivating equilibrium it may be generally uniform throughout, which may be very favorable from a shunt resistance perspective.

Depending on deposition conditions, various amounts of the metal may be deposited on the nanostructures. The cavities in the nanostructures may be completely filled, the nanostructures may be partially filled, the surfaces of the nanostructures (e.g., the surfaces defining the cavities) may be completely covered, or the surfaces of the nanostructures may be partially covered. In some embodiments, such as the embodiment illustrated in FIG. 1A, it may be desirable for the cavities to be completely filled. In other embodiments, such as the embodiments illustrated in FIGS. 1B and 1C, it may be desirable for the surfaces to be completely covered, but the cavities to not be filled. In one embodiment, it is desirable to achieve a high quality (i.e., complete) filling or coating of the nanostructure to avoid the nanostructures 12 contacting the hole-conductor material 19, resulting in a low shunt resistance (short circuiting).

Below are described non-limited working examples of electrodeposition conditions for iron (Fe) and copper (Cu). Both Fe₂O₃ and Cu₂O have high extinction coefficients for wavelengths below their band gaps (α>10⁵cm⁻³) but also have very high resistivity (0.1-10⁵ kΩcm). The charge carriers generated by absorption may be efficiently extracted be keeping the absorbing oxide layers relatively thin (e.g., typically <20 nm in the case of Fe₂O₃). In some embodiments, the band gap properties of Fe₂O₃ and Cu₂O make them desirable for fabrication of the solar cell 10. In other embodiments, other metals such as cobalt (Co), nickel (Ni), palladium (Pd), gold (Au) and their oxides having desirable band gap properties may be deposited in a similar manner.

### Electrodeposition of Iron

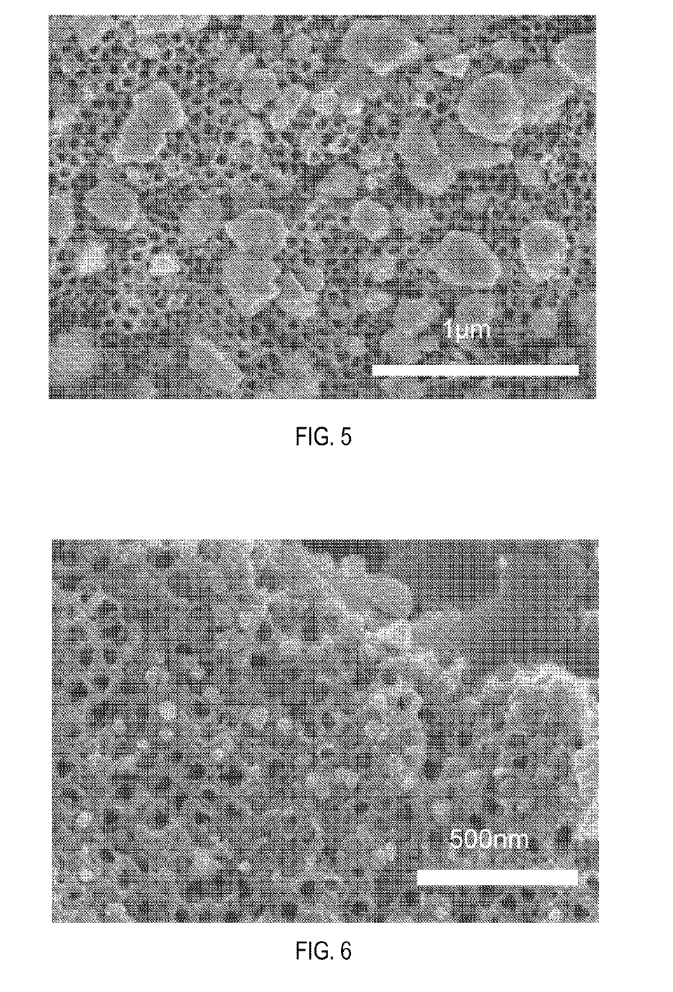

Electrodeposition of iron onto the nanostructures may be performed in an aqueous electrolyte solution containing 10 g iron sulfate (FeSO₄), and 2.5 g boric acid (H₃BO₃) in 250 ml of deionized water. In one embodiment, the nanostructures are anodized under decreasing AC voltage, followed by DC voltage, starting right below the anodization voltage that was used for the original synthesis of the nanostructures. In the solution, the iron sulfate dissociates into Fe³⁺ and SO₄²⁻ ions and by appropriately adjusting the applied voltage, the Fe³⁺ ions may be reduced to Fe ions which deposit inside the cavities. An example of iron electrodeposited in a nanotube array is shown in FIG. 5.

In one embodiment, iron is deposited onto nanotubes produced by anodization under 30V DC. The deposition is performed first under AC voltage (frequency f=250 Hz), starting with 25V, then in steps of 15V, 10V, 7V, and 4V respectively. Final deposition is performed under DC voltage, in steps of 2V and 1V. The duration of each step is 30 seconds.

In another embodiment, iron is deposited onto nanotubes produced by anodization under 20V DC. The deposition is performed first under AC voltage (frequency f=250 Hz), starting with 15V, then in steps of 10V, 7V, and 4V respectively. Final deposition is performed under DC voltage, in steps of 2V and 1V. The duration of each step is 10 seconds.

### Electrodeposition of Copper Oxide

Electrodeposition of copper onto the nanostructures is performed in an aqueous electrolyte solution containing 0.3 M copper sulfate (CuSO₄), 1.5 M citric acid, and about 5M sodium hydroxide. The sodium hydroxide is included to achieve a desired pH of about 11. The deposition is performed under a pulsing voltage (frequency f=1 Hz), with a pulse of V=2V for 0.25 s, followed by a relaxation time of 0.75 s for each is cycle. The total deposition time is between 2 and 3 minutes. An example of copper oxide electrodeposited in a nanotube array is shown in FIG. 6.

### Thermal Evaporation Deposition of Iron

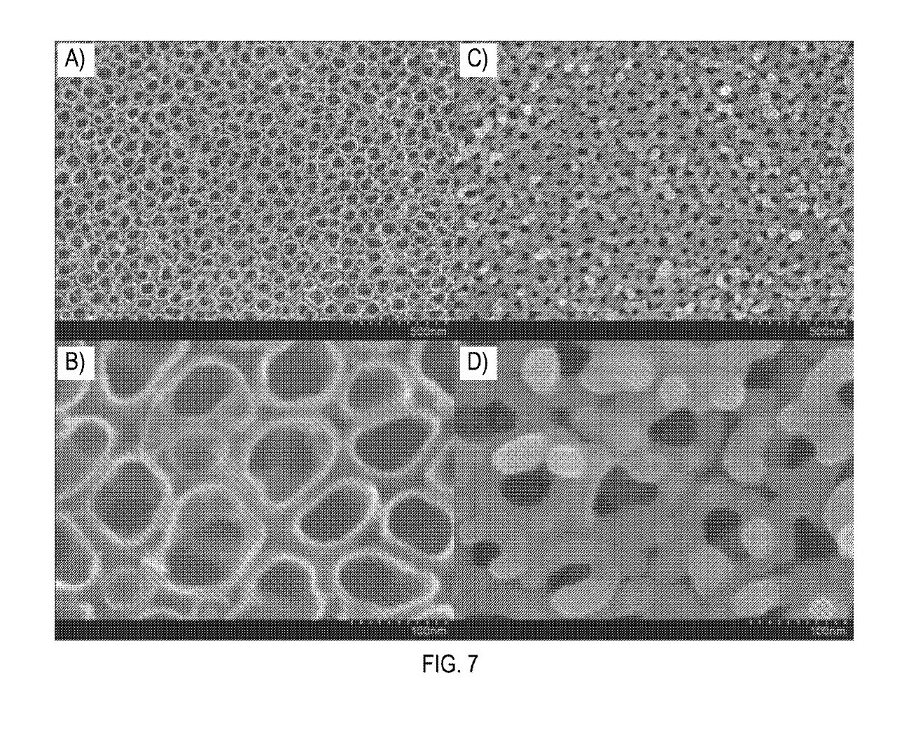

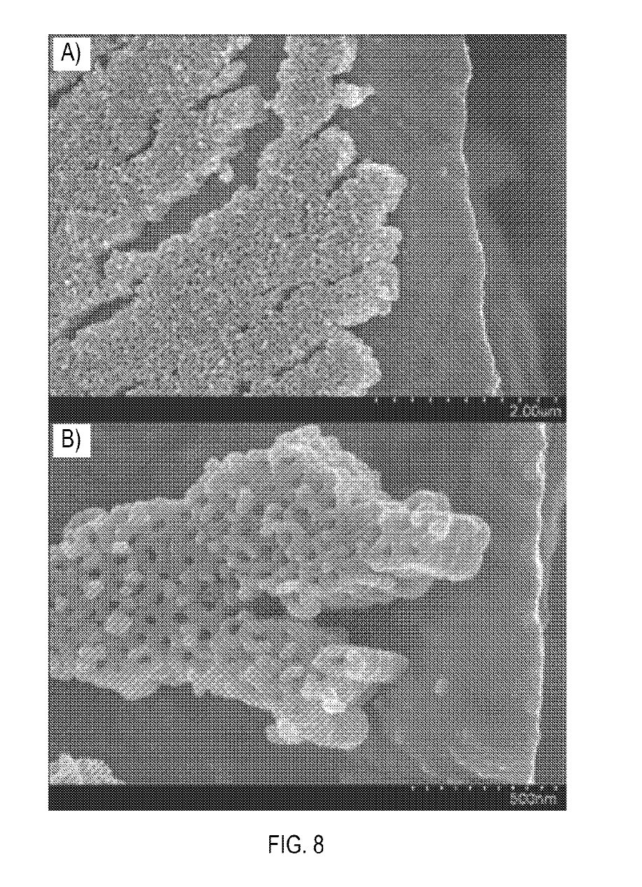

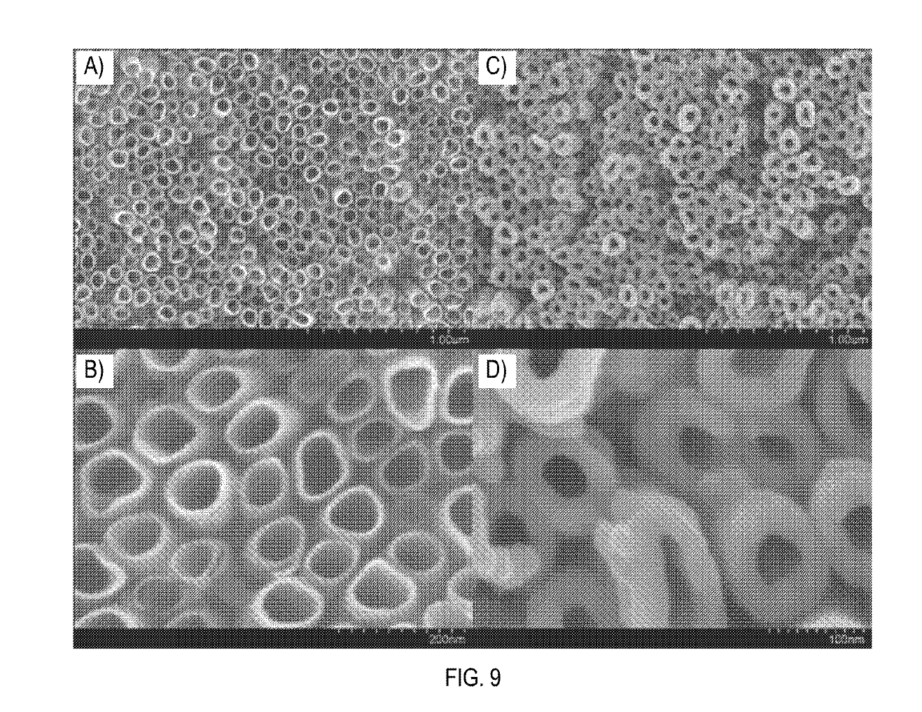

The absorber layer may alternatively be deposited onto the nanotubes by thermal evaporation. Both iron and copper have been successfully deposited by this method. The metal content may be controlled by varying the deposition parameters such as deposition rate and total deposition time. In one embodiment, the nanostructures are coated with iron at a rate between 0.1 nm/s and 1 nm/s. In one embodiment, the total deposition time is between 1 min. and 10 min. An example of iron thermally deposited on a nanotube array is shown in FIGS. 7A-9D.

Subsequent heat treatment (annealing) may be employed to oxidize the metal inside the nanotubes.

### Characterization of Deposited Absorber Layer

After deposition of the metal oxide absorber layer, the nanostructure array may be investigated both visually (SEM, TEM) and analytically (electron diffraction spectroscopy and elemental mapping, magnetometry, X-Ray diffraction etc.)

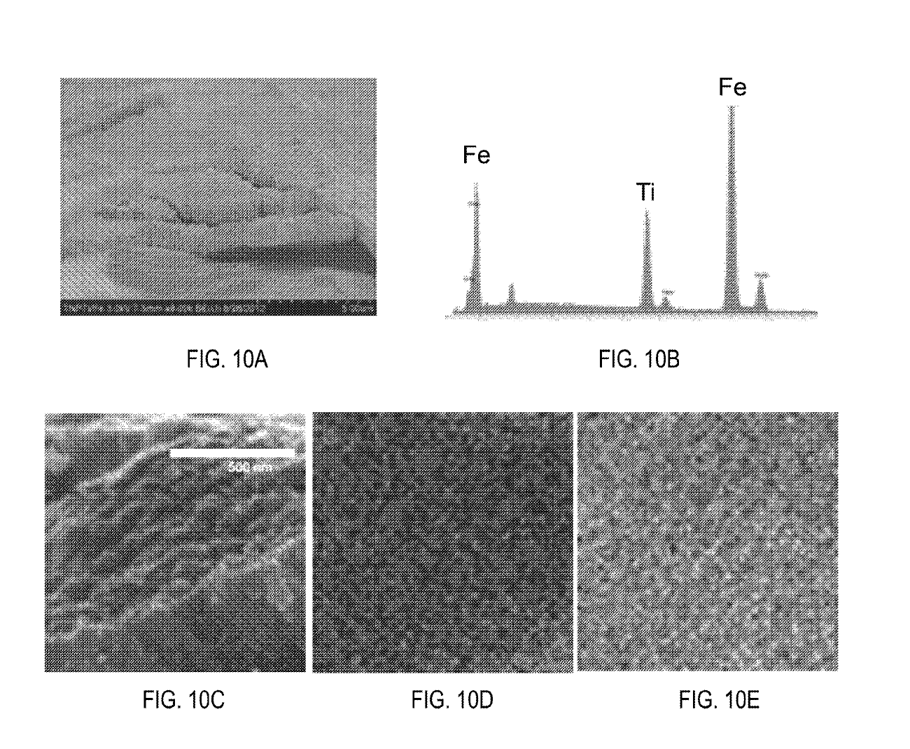

Referring to FIGS. 10A-10E, the presence of various elements, including titanium and iron, is shown for a titania nanopore array coated with iron. The iron is deposited such that the pores are generally completely filled with iron. The electron diffraction spectroscopy in FIG. 10B illustrates a relatively large amount of iron. The elemental maps in FIGS. 10D and 10E illustrate a relatively constant distribution of iron and titanium in the structure.

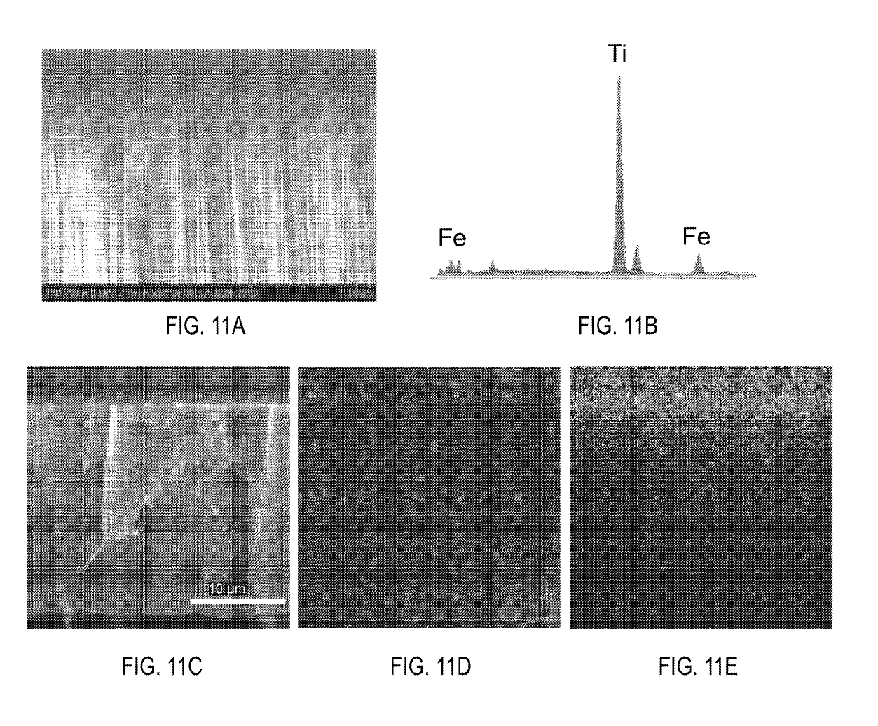

Referring to FIGS. 11A-11E, the presence of various elements, including titanium and iron is shown for a titania nanotube array coated with iron. The iron is deposited such that interior of the nanotubes is partially filled with iron. The electron diffraction spectroscopy in FIG. 11B illustrates an amount of iron that is less than the amount of titanium. The elemental maps in FIGS. 11D and 11E illustrate a relatively constant distribution of titanium, but a distribution of iron that is concentrated near the open tops of the nanotubes.

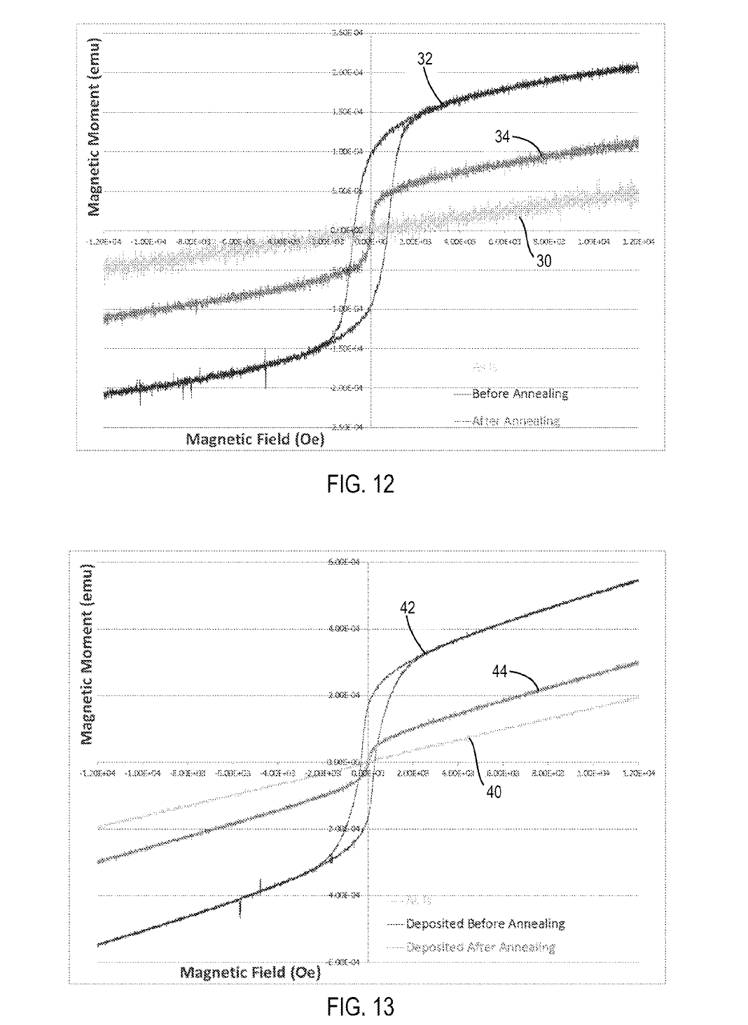

Referring to FIGS. 12 and 13, graphs illustrating the magnetic properties of the nanostructure array are shown before deposition of the metal, after deposition of iron, and after thermal treatment (e.g., annealing). The magnetic properties are measured in order to establish the ferromagnetic properties. The graphs were made with data gathered from about 3 mm×3 mm samples of a relatively short nanotubes (e.g., less than 500 nm long) in FIG. 12 and relatively long nanotubes (e.g., more than 10 microns) in FIG. 13. The data were analyzed using a MicroMag 2900 alternate gradient magnetometer at room temperature.

Before deposition of the iron, the samples of nanotubes exhibited paramagnetism, specific to titanium oxide, as shown with lines 30 and 40. After iron deposition, a ferromagnetic signal was been observed on top of the initial paramagnetic signal, with coercivity values below 1 kOe, and saturation moment values of few hundred μem, as shown with lines 32 and 42. After subsequent annealing of the samples, while the crystalline titanium oxide paramagnetic behavior did not change significantly, the iron inside the nanotubes was oxidized, resulting in much lower values of the coercivity, while the saturation moment decreased by more than a half, as shown with lines 34 and 44.

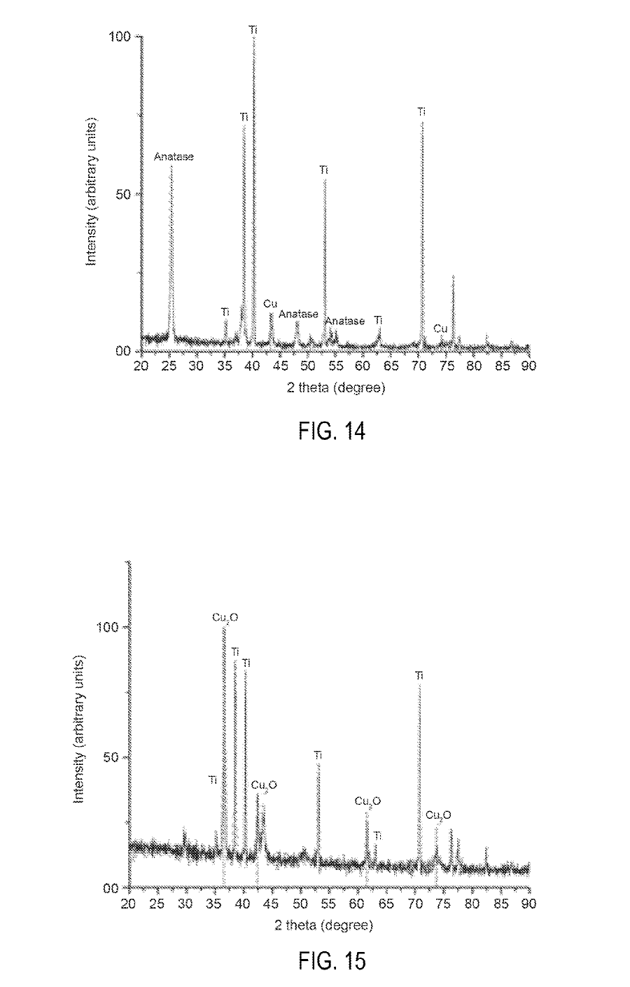

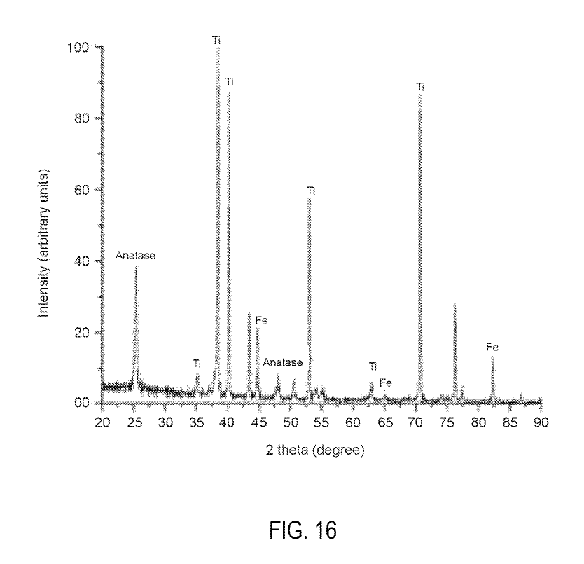

FIGS. 14-16 illustrate x-ray diffraction (XRD) spectra of the nanotube array in one embodiment. XRD may be also used in order to analyze the materials deposited inside the titania nanotubes. FIG. 14 illustrates an XRD spectra for a sample of titania nanotubes onto which copper is deposited. FIG. 15 illustrates an XRD spectra for a sample of titania nanotubes onto which copper oxide (Cu₂O) is deposited. FIG. 16 illustrates an XRD spectra for a sample of titania nanotubes onto which iron is deposited. The titanium signal is detected from the underlying titanium foil supporting the nanotubes arrays, and the crystalline TiO₂ (anatase) signal is present for samples that have been annealed.

### Conductor Layer

A conductor layer may be one that comprises a metal conductor or semiconductor. In addition to the metal oxide absorber layer formed on the surface of the cavities in the nanostructures, the remainder of the cavity is filled at least partially (or completely in some embodiments) with a filler material, such as a metal conductor. The metal conductor may, for example, comprise iron or copper metal (as shown in FIG. 1A). The cavity may also be filled at least partially (or completely in some embodiments) with filler material, such as a hole-conductor material, such as CsSnI₃ (as shown in FIGS. 1B and 1C).

According to an exemplary embodiment, the metal conductor may be disposed over a surface in the cavity of the nanostructures using any suitable technique. For example, it can be disposed using a deposition involving the anodizing process described above, with the anodizing parameters being chosen to achieve complete filling of the cavities in the nanostructures. Oxygen transfer from the nanostructure array to the deposited metal (controlled by annealing temperature and oxygen partial pressure) may transform a portion of the deposited metal to a thin metal oxide absorber layer on the surface of the nanostructure array.

According to another exemplary embodiment, the anodizing parameters for the deposition of the metal may be chosen to achieve a complete coating of the cavities of the nanostructures, leaving the remainder of the nanostructures hollow. The cavities may then be filled with CsSnI₃ or another suitable hole conductor material, such as such as spiro-OMETAD, PEDOT, P3HT, etc. The hole conductor material may be either an n-type semiconductor or a p-type semiconductor, depending on the material comprising the nanostructure array.

### Nanoparticles

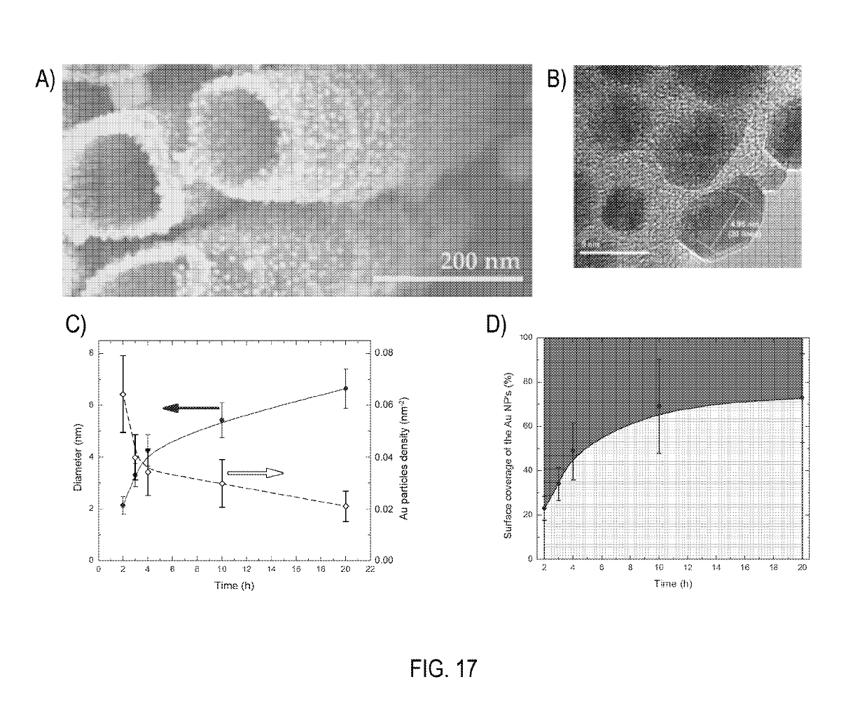

In some embodiments, at least a portion of the cavities in the nanostructures may be lined with nanoparticles, used for plasmonic enhancement, prior to being coated with the metal oxide absorber layer. Charge separation and photon absorption in nanostructures, such as those comprising titania may be plasmonically enhanced by disposing over the array certain nanoparticles comprising at least one metal, such as a noble metal (e.g., Au), prior to integration with metal oxides. In one embodiment, these nanoparticles provide enhanced photoabsorption due to the strong local electric field generated by plasmonic resonances that may be tailored by controlling the size and density of the nanoparticles. Referring to FIGS. 17A-17D, titania nanotube arrays may be uniformly coated with gold nanoparticles both inside and outside the surface. In one embodiment, the nanoparticles are chemically deposited onto the nanotubes by soaking the nanotubes in a mixture (with controlled pH) of sodium hydroxide (NaOH) and hydrogen tetra-aurochlorate (HAuCl₄) solution. A relatively controlled range of diameters (in the range of 1-10 nm) and coverage percentage (up to 70%) of the deposited gold nanoparticle may be achieved by adjusting the soaking time. In one embodiment, deposition of gold nanoparticle with diameters <5 nm and coalescence of nanoparticle to almost total coverage of the nanotube surfaces with a thin layer (˜10 nm) of metallic gold after long time exposure to the gold solution may be carried out. In one embodiment, the gold nanoparticles have a diameter between approximately 1 nm and 20 nm. In another embodiment, the gold nanoparticles have a diameter between approximately 1 nm and 10 nm. In another embodiment, the gold nanoparticles have a diameter of approximately 3 nm. In one embodiment, Au-nanoparticle or Au-nanofilm decorated titania may be a highly plasmonic materials with enhanced solar absorption.

### Contacts

Conductive contacts may be formed on the array of nanostructures through which the nanostructures, the metal oxide absorber layer, and the filler material in the cavities are connected in a closed electric circuit. The first contact may be formed on the upper side of the nanostructure array. The second contact may be formed on the lower side of the nanostructure array, opposite of the first contact. In one embodiment, both the first contact and the second contact are formed of all metal (e.g., copper for the first contact and titanium for the second contact). In another embodiment, at least one of the first contact and the second contact comprises a transparent conductive oxide. The transparent conductive oxide may be, for example, indium tin oxide. In another embodiment, the top contact is formed of a transparent conducting oxide, such as indium tin oxide.

### Performance of the Solar Cell

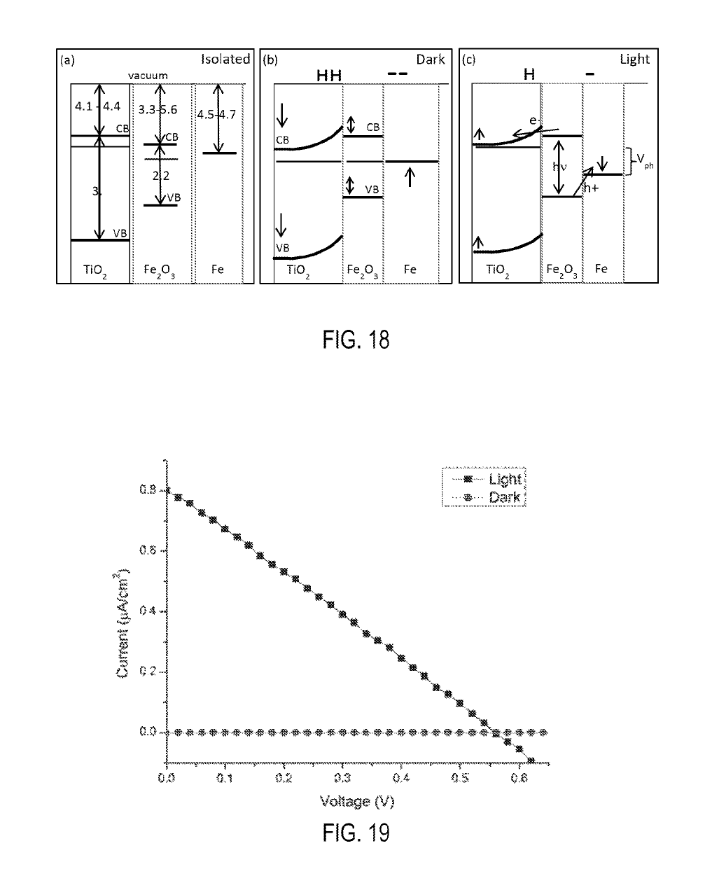

The titania nanostructure, the metal oxide absorber layer, and the filler material may form a metal-insulator-semiconductor (MIS) cell. For example, the MIS cell system may be a TiO₂∥Fe₂O₃∥Fe system or a TiO₂∥Cu₂O∥Cu, as described above. The operating principles of an n-type MIS cell in one embodiment are illustrated in FIG. 18. Because of the high resistivity of Fe₂O₃ and/or Cu₂O, it is desirable that the absorber/insulator layer be kept thin, thereby resulting in little light absorption for a planar structure results. In one embodiment, the nanostructured solar cells and the relevant energy level alignments of these materials may a suitable photovoltage and an appropriate rectifying field for charge separation under illumination.

Not to be bound by any particular theory, but conventionally the “best” metals for n-type MIS solar cells in at least some instances are Ag (φ=4.3-4.7 eV), Au (φ=4.3-4.7 eV), Pt (φ=4.3-4.7 eV) and Pd (φ=4.3-4.7 eV). The metals employed in the embodiments herein exhibit similar work functions (φCu=φFE=4.5-4.7 eV). However, these convention models and the standard Schottky-Mott model apply to bulk systems. In the MIS systems provided herein, the semiconductor layer thickness (TiO₂ nanotube or pore walls) may be between 10 nm and 200 nm. In another embodiment, the semiconductor layer thickness may be between 20 nm and 100 nm. In another embodiment, the semiconductor layer thickness may be between 30 nm and 70 nm. However, a thickness of approximately 200 nm is much thinner than the typical depletion layer for a metal-TiO₂ Schottky junction (1.5 μm-0.5 μm estimated by Schottky-Mott model with native free carrier density 10⁻¹⁵-10⁻¹⁸ cm⁻³).

Experiments were conducted to determine the band alignment of a TiO₂∥Fe₂O₃∥Fe nanostructure MIS cell provided in one non-limited working example. Referring to FIG. 19, the I-V curve for a solar cell not yet optimized including a TiO₂ nanotube array with Fe electrodeposited and Cu top contacts is shown. The solar cell architecture fabricated and employed in this example was similar to the solar cell illustrated in FIG. 1A. The simple preliminary cell had a copper front contact instead of a TCO front contact and no annealing to reduce nanotube conductivity and optimize the absorber layer. High series resistance (a low fill factor) was observed. However, a V_{OC} of 0.56 V (measured under calibrated standard AM 1.5 illumination) was observed, which is promising for such a simple, non-optimized device. As with the TiO₂∥Cu₂O∥Cu system, this result show that for the TiO₂∥Fe₂O₃∥Fe system the correct band alignment was achieved (with TiO₂ the external electron source and Fe the sink) and moreover a high V_{OC} was observed for a non-optimized device.

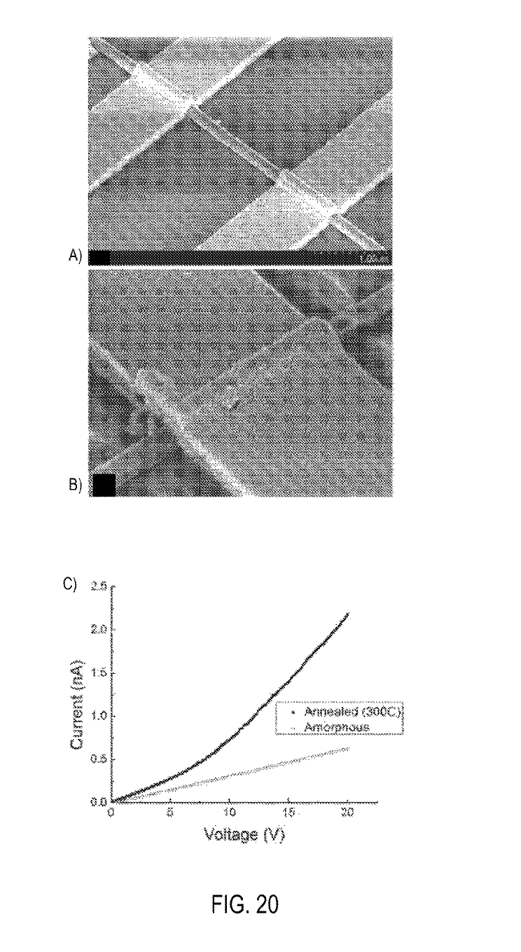

Electron transport in titania nanotube arrays was measured through time-resolved terahertz (FIR) spectroscopy and single nanotube conductivity measurements and examined. Measurements on the carrier transport, charge mobility, electrical resistivity by traditional transport measurements at the single tube level corroborate the improved charge transport. Referring to FIGS. 20A-20C, current-voltage and transistor characteristics were measured utilizing photolithography/e-beam lithography to attach source/drain/gate electrodes onto single nanowires/nanotubes in one non-limiting working example. According to an exemplary embodiment, the electrodes have a thickness of approximately 200 nm and the titania nanotube has a diameter of approximately 150 nm. The measured data indicates low resistances for the nanotubes (˜2.3×10² Ω·m) compared to anatase titania nanoparticles (˜10⁵ Ω·m).

### Applications

The ultra-low-cost solar cells described above may be used in a variety of applications, including, but not limited to, hand-held devices, automobile and building-integrated photovoltaics, and large scale solar energy installation, such as a solar farm in a desert region where low $/kWh is a more desirable parameter than kWh/m2 land area used.

In one embodiment, the solar cell 10 and methods for constructing the solar cell as described above may have advantages over pre-existing solar cell technologies and technologies under development in the materials used, the manufacturing techniques, and the architecture of the cell.

The all-inorganic solar cell utilizes titania nanotube arrays integrated with ultra-low-cost, abundant and stable materials such as iron oxide (rust), copper oxide, etc.

The majority of the solar cell architecture may be manufactured in a two-step electrochemical process that is similar to electrochemical anodization and electroplating techniques already used in low cost industrial manufacturing. Most of the solar cell may be fabricated in two steps: anodization and electrodeposition. Both of these processes are relatively easy to scale up and low cost nanofabrication techniques. In one embodiment, a cell ready for module encapsulation may be completed with steps including a rapid low temperature anneal, the optional addition of a melt-processed hole conductor, transparent conducting oxide (TCO) deposition and front contact deposition or printing. These steps have a substantial cost benefit over the multiple vacuum and high temperature or chemical vapor deposition steps needed in the manufacturing of standard Si PV, or thin film technologies like CIGS or CdTe. The all-electrochemical approach for the primary cell assembly allows this approach to be inexpensive from a material perspective, as well as from the processing-cost perspective.

The solar cell in some embodiments herein may be an all-solid state solar cell which may avoid the deficiencies of some pre-existing alternative solutions such as dye-sensitized solar cell which use a corrosive liquid redox-couple electrolyte. In these pre-existing liquid electrolytes are challenging to integrate into commercially viable products.

A highly desirable ultra-fast charge transfer process at the semiconductor interface is ensured by having only a thin nano-clusters or nanolayer of the light absorbing material (e.g., Fe₂O₃ or Cu₂O) where photons are absorbed close to the interface and charges are rapidly separated by injection. The utilization of one-dimensional nanotubular architecture for the semiconductor photoanode allows for multiple advantages, such as increased light trapping, enhanced effective surface area for absorber decoration and photo-absorption.

### Additional Notes

All literature and similar material cited in this application, including, but not limited to, patents, patent applications, articles, books, treatises, and web pages, regardless of the format of such literature and similar materials, are expressly incorporated by reference in their entirety. In the event that one or more of the incorporated literature and similar materials differs from or contradicts this application, including but not limited to defined terms, term usage, described techniques, or the like, this application controls.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” Any ranges cited herein are inclusive.

The terms “substantially” and “about” used throughout this Specification are used to describe and account for small fluctuations. For example, they may refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

1. A solar cell, comprising:
a plurality of nanostructures, comprising a first metal oxide, each of the plurality of the nanostructures having a surface defining a cavity opening into an upper side;
a layer disposed over the surface in at least some of the plurality of the nanostructures, the layer comprising a second metal oxide; and
a filler material disposed over the layer and filling at least partially the cavity of at least some of the plurality of the nanostructures.

2. The solar cell of claim 1, further comprising:
a first contact disposed over a portion of the plurality of nanostructures at the upper side and in contact with the filler material; and
a second contact disposed over a lower side of the plurality of nanostructures opposite the first contact.

3. The solar cell of claim 2, wherein at least one of the first contact and the second contact comprises a transparent conductive oxide.

4. The solar cell of claim 1, wherein the first metal oxide comprises titania.

5. The solar cell of claim 1, wherein the plurality of nanostructures comprises an array of nanotubes having lengths of between about 5 microns and about 10 microns.

6. The solar cell of claim 1, wherein the plurality of nanostructures comprises at least one of nanopores and nanowires.

7. The solar cell of claim 1, wherein the layer comprises at least one of iron oxide and copper oxide.

8. The solar cell of claim 1, wherein the layer has a thickness of less than 20 nm.

9. The solar cell of claim 1, wherein the filler material comprises at least one of a metal conductor or a semiconductor.

10. The solar cell of claim 1, further comprising nanoparticles disposed between the layer and the plurality of nanostructures, wherein the nanoparticles comprise at least one metal.

11. A method for making a solar cell, comprising:
disposing a layer comprising a metal on a surface of at least some of a plurality of nanostructures, the surface defining a cavity in the plurality of nanostructures;
forming a metal oxide layer by heat treating the layer comprising the metal;
disposing a filler material on the metal oxide layer, the filler material filling at least partially the cavity of at least some of the plurality of nanostructures.

12. The method of claim 11, further comprising forming the plurality of nanostructures by anodizing titanium at a first voltage.

13. The method of claim 12, wherein the disposing of the layer comprising the metal further comprises electrodepositing the metal at a second voltage using a solution comprising a salt of the metal, wherein the second voltage is less than the first voltage.

14. The method of claim 13, wherein the first voltage is 30V DC, and wherein the layer comprises iron formed by electrodeposition using a solution containing iron sulfate sequentially at decreasing voltages of 25V AC, 15V AC, 10V AC, 7V AC, 4V AC, 2V DC, and 1V DC, each voltage being applied for 30 seconds.

15. The method of claim 13, wherein the first voltage is 20V DC, and wherein the layer comprises iron formed by electrodeposition using a solution containing iron sulfate sequentially at decreasing voltages of 15V AC, 10V AC, 7V AC, 4V AC, 2V DC, and 1V DC, each voltage being applied for 10 seconds.

16. The method of claim 13, wherein the layer comprises copper formed by electrodeposition using a solution containing copper sulfate at a decreasing pulsing voltage of 2V DC, the voltage being applied for a duration of 0.25 s at a frequency of 1 Hz.

17. The method of claim 11, wherein disposing the layer further comprises thermal evaporation.

18. The method of claim 11, wherein the filler material comprises at least one of iron, copper, and CsSnI₃.

19. The method of claim 11, further comprising depositing nanoparticles on the surface before disposing the layer, wherein the nanoparticles comprise at least one metal.

20. The method of claim 11, further comprising annealing the nanostructure at 400° C. for 1 hour before disposing the layer on the surface.

21. A solar cell, comprising:
a plurality of nanotubes comprising titania, each of the plurality of the nanotubes having a surface defining a cavity opening into an upper side;
a layer disposed over the surface of at least some of the plurality of the nanotubes, the layer comprising a metal oxide;
a filler material disposed over the layer and filling at least partially the cavity of at least some of the plurality of the nanotubes;
a first contact disposed over a portion of the plurality of nanotubes at the upper side and in contact with the filler material; and
a second contact disposed on a lower side of the nanotubes opposite the first contact.

22. The solar cell of claim 21, wherein at least one of the first contact and the second contact comprises a transparent conductive oxide.

23. The solar cell of claim 21, wherein the layer comprises at least one of iron oxide and copper oxide.

24. The solar cell of claim 23, wherein the layer has a thickness of less than 20 nm.

25. The solar cell of claim 21, wherein the filler material comprises at least one of iron, copper, and CsSnI₃.

26. The solar cell of claim 21, further comprising gold nanoparticles disposed between the layer and the plurality of nanotubes.
